(19) United States
(12) Patent Application Publication
(10) Pub. No.: US 2009/0315129 A1
(43) Pub. Date: Dec. 24, 2009

(54) INTEGRATED CIRCUIT DISTRIBUTED OVER AT LEAST TWO NON-PARALLEL PLANES AND ITS METHOD OF PRODUCTION

(76) Inventor: Jean Baptiste Albertini, Crollies (FR)

Correspondence Address: BRINKS HOFER GILSON & LIONE, P.O. BOX 10395, CHICAGO, IL, 60610, US

(21) Appl. No.: 12/373,444

(22) PCT Filed: Jul. 11, 2007
(86) PCT No.: PCT/FR07/01188

§ 371 Date: Jan. 12, 2009

(30) Foreign Application Priority Data
Jul. 13, 2006 (FR) 0652966

(51) Int. Cl. H01L 43/00; H01L 21/3205; H01L 21/64; H01L 23/52

(52) U.S. Cl. 257/427; 438/669; 29/25.01; 257/734; 257/E43.001; 257/E21.294; 257/E23.141

(57) ABSTRACT

An integrated circuit includes a first plate-shaped part and at least a plate-shaped second part separate from the first part and attached to the first part by deformable mechanical connection defining a non-zero angle with the first part. A method of producing the integrated circuit includes depositing deformable connecting means in contact with a first portion of the structure and a second portion of the structure, etching the structure to separate the first portion and the second portion, relatively moving the first and second portions to deform the connecting means and fastening together the first portion and the second portion.

### PRIORITY CLAIM

This application is a U.S. nationalization of PCT Application No. PCT/FR2007/001188, filed Jul. 11, 2007, and claiming priority to French Patent Application No. 0652966, filed Jul. 13, 2006.

### TECHNICAL FIELD

The invention concerns an integrated circuit distributed over at least two non-parallel planes, including for example an electrical circuit, a magnetic circuit or an electronic circuit, or of MEMS (MicroElectroMechanical System) type, and a method of production of such integrated circuits. It can in particular be a question of a microelectronic component or a component produced using techniques from the field of micro- or nano-technologies.

### BACKGROUND

Components are frequently used having a portion consisting of at least one plate-shaped structure one face of which carries an electrical circuit. In the context of microelectronics, for example, a substrate can carry electronic circuits such as magnetic field sensors.

It is sometimes required to dispose at least a portion of the circuit in a plane inclined, or even perpendicular, to the plane defined by the plate.

This is the case in particular when it is required to measure a magnetic field in three dimensions, for example as described in U.S. Pat. No. 5,446,307.

In that document, magnetic sensors are placed so that each measures the component of the magnetic field perpendicular to one of the inclined faces of a pyramidal structure, which is a simple way to provide access to the three components of the magnetic field.

The front face etching technology used to obtain the pyramidal structure limits the height that can be envisaged for that structure to a few micrometers, however, and means that this solution cannot be applied to magnetic sensors of larger size (for example with dimensions of the order of 1000 μm), the use of which on the inclined faces of the structure would result in much too low an inclination of the latter (less than 1% inclination) to be able to measure efficiently the magnetic field in a direction other than perpendicular to the substrate.

PCT Patent Publication No. WO 2006/001978 proposes a solution of the same type.

The above two inventions also have the major drawback that the electrical or microelectronic circuits must be produced on inclined planes, which gives rise to numerous difficulties.

### SUMMARY

The invention therefore aims in particular to propose an alternative solution for producing a component having faces inclined to each other, possibly with a significant inclination, and in particular, starting with a plate-shaped structure, a plane inclined to the rest of that structure. This inclined plane could advantageously include, before or after inclination, a magnetic sensor in the context of microelectronics or any other microelectronic device.

In this context, the invention proposes an integrated circuit including a plate-shaped first portion (carrying in a general manner a circuit), characterized in that it includes at least one second plate-shaped portion separate from the first portion, attached to the first portion, connected to the first portion by deformable mechanical connecting means and forming a non-zero angle with the first portion.

Because the two portions are separate, they are independent (at least during part of the process of producing the integrated circuit) and can be moved freely relative to each other to their reciprocal final position, whilst nevertheless being retained by the deformable connecting means.

Thus all of the elements (such as electrical circuits) can be produced on the two portions in the same plane, after which one portion is moved relative to the other to obtain elements distributed over two non-parallel faces.

The connecting means are at least in part of metal, for example, enabling them to be used also as electrical conductors, where appropriate.

In practice, the connecting means can include at least one metal wire fastened to the first portion at one end and to the second portion at the opposite end. In another embodiment, the connecting means can include at least one metal trellis connected to the first portion and to the second portion.

The connecting means can be produced in copper or in gold, particularly suitable because of their flexibility.

For example, the first portion includes a silicon plate.

For example, according to the invention, the angle between the first and second portions is greater than 60°, or even equal to approximately 90°, for example to within 10°.

When the second portion carries an electrical element the connecting means can contribute to an electrical connection between an electrical circuit carried by the first portion and the electrical element carried by the second portion.

For example, the electrical circuit carried by the first portion includes at least one sensor adapted to measure a magnetic component in a direction parallel to a main surface of the first portion and the second portion can carry a sensor adapted to measure a component of the magnetic field in a direction parallel to a main surface of the second portion.

For example, the sensors are micro-fluxgate sensors, magnetoresistive sensors, magneto-impedance sensors or Hall-effect sensors.

When the first portion carries a plurality of first connection studs, another integrated circuit having second connection studs can be mounted in contact with the first portion, with electrical connection between at least one of said second connection studs and one of said first connection studs (for example thanks to the interposition of conductive balls, by means of anisotropic conductors or by thermocompression). This produces a particularly compact structure.

The second portion can then be near a flank of the other integrated circuit, which makes the assembly even more compact.

In an embodiment described hereinafter, the plates are obtained from substrates conventionally used in microtechnology, for example in semiconductor material, such as silicon, germanium (or III-V or II-VI materials); the plates are then essentially rigid (in particular, essentially incapable of being curved) given the dimensions characteristic of such substrates.

The invention also proposes a method of producing an integrated circuit from a plate-shaped structure (which generally carries a circuit), including the following steps:

depositing deformable connecting means in contact in particular with a first portion of the structure and a second portion of the structure;

etching the structure to separate the first portion and the second portion;

relatively moving the first and second portions, leading to deformation of the connecting means;

fastening together the first portion and the second portion.

This method can also include a step, after the movement step, of fastening together the first and second portions (directly or via another portion), a non-zero angle then existing between their respective main surfaces.

For example, the movement is a rotation of the second portion relative to a hinge formed by the connecting means.

The connecting means can be deposited during at least one of the technology steps of producing the circuit carried by the plate-shaped structure.

The method can also include a step of thinning the structure before etching it and/or a step of partial grinding of an area subjected to said etching before the etching step.

When the connecting means are produced in an electrically conductive material, there can be a step of depositing a conductor between at least one circuit carried by the first portion or the second portion of the structure and the connecting means, in order to make the electrical connection to these various elements.

When the conductor is deposited between a circuit of the second portion and the connecting means, the method can further include a step of depositing a conductor between the connecting means and a circuit element on the first portion, in order to extend the connection previously produced.

The etching can be precisely localized anisotropic etching.

The face of the second portion that has been subjected to etching (rear face) can be assembled to the edge of the first portion (in particular, a lateral face of the first portion, different from the main faces of the plate).

In another embodiment, the etching step can form an inclined profile on a face of each of the first and second portions receiving the etching. The movement step can then move the inclined profile of the second portion near (or even into contact with) the inclined profile face of the second portion, and there can then be a further step, after the movement step, of assembling the inclined profile of the second portion against the inclined profile face of the second portion, which produces a particularly compact and robust structure. The assembly process can include sticking the two portions together (for example by depositing a bead of glue that can further make good any interstice between the two portions).

### BRIEF DESCRIPTION OF THE DRAWING

Other features and advantages of the invention will become more clearly apparent in the light of the following description, given with reference to the appended drawings, in which:

FIGS. 1 and 2 represent two of the steps of producing an integrated circuit conforming to the teachings of the invention;

FIG. 3 represents in perspective an integrated circuit obtained by such a method, before bending one of its portions;

FIG. 4 represents the assembly of the integrated circuit from FIG. 3 and another integrated circuit;

FIG. 5 is a diagram of a second embodiment of the invention;

FIGS. 6 and 7 are diagrams of a third embodiment of the invention; and

FIGS. 8 and 9 show alternatives to the deformable connecting means provided in the previous embodiments.

### DETAILED DESCRIPTION

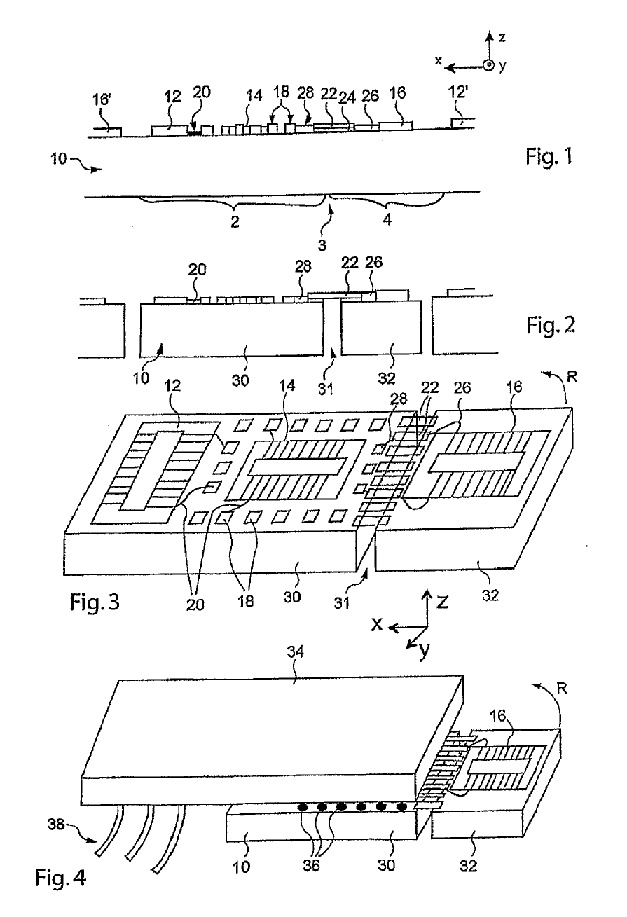

FIG. 1 represents a substrate 10, here in silicon, onto the front face of which have been deposited elements of an electrical circuit, including three magnetic field sensors 12, 14, 16.

Each sensor 12, 14, 16 is adapted to measure the magnetic field in a given direction and three magnetic field sensors 12, 14, 16 are therefore provided to obtain measurements of the local magnetic field projected in the three directions in space (X, Y, Z), i.e. the three components of this magnetic field.

A first sensor 12 and a second sensor 14 are situated in a first region 2 of the substrate 10 and are disposed perpendicularly to each other in order to measure the respective components of the magnetic field in the direction Y and in the direction X. (These latter two directions X, Y are essentially parallel to the front face of the substrate 10.)

A second region 4 of the substrate 10 carries the third sensor 16. In this example this sensor is parallel to the second sensor 14, but is intended to measure the component of the magnetic field in the direction Z normal (i.e. perpendicular) to the front face of the substrate 10 (which carries the aforementioned elements), in the manner described hereinafter.

Each magnetic sensor is produced using the micro-fluxgate technology, for example. Alternatively, these could be magneto-resistive sensors (in particular AMR, GMR or TMR sensors), magneto-impedance (MI) sensors, or Hall-effect sensors.

The front face of the substrate 10 also carries connection studs 18 some of which are connected to a corresponding sensor by means of conductors 20 (for example conductive tracks, possibly separated from the substrate by a layer of insulative material).

A plurality of metal (here copper) tracks (or wires) 22 have equally been deposited on the front face of the substrate 10, at the boundary between the first region 2 and the second region 4, encroaching of each of those two regions, and here with an interposed insulator 24 (for example silicon oxide).

In practice, the insulative layer 24 could extend over the whole surface of the substrate 10 in order to insulate the elements described above.

Some of the metal tracks 22 are electrically connected to the magnetic sensor 16 in the second region 4, for example by a conductor 26. These same metal tracks 22 are also electrically connected to one of the connection studs 18 in the first region 2, by a conductor 28.

Thus the magnetic sensor 16 in the second region 4 of the substrate 10 is electrically connected to connection studs 18 in the first region 2 of the substrate 10 via at least one of the metallic tracks 22 in particular.

The various conductors 20, 26, 28 are, for example, copper or gold tracks deposited during the production of the other elements carried by the substrate 10 (for example by the same technique as the metal tracks 22, possibly during the same technology step). Alternatively, the conductors could be formed by gold wires produced after construction of the other elements carried by the substrate.

It may be noted here that a plurality of components (integrated circuits) can be obtained from the same substrate 10 using collective integrated circuit production technology. There can therefore be seen in FIG. 1 a magnetic field sensor 16′ located near the first sensor 12 and a magnetic field sensor 12′ located near the third sensor 16, these sensors 16′, 12′ being each intended for a component of the same type as that described above and obtained in parallel.

Once the various elements referred to above and visible in FIG. 1 have been deposited on the front face of the substrate 10, the rear face of the substrate 10 is etched to eliminate the entire thickness of the substrate over a portion of limited extent situated at the boundary between the first region 2 and the second region 4. There is produced for example in this step, by protecting the portion of the substrate to be retained (in practice virtually all of the substrate) by means of photolithography and applying anisotropic etching to the rear face, for example deep reactive ion etching (DRIE), or by chemical etching (for example using KOH when the substrate 10 is of silicon).

In one embodiment that can be envisaged, this rear face etching step can separate the various components formed from the same substrate. Alternatively, the different components produced from the same substrate could naturally be separated in a later step.

Moreover, another etching step could be used (for example appropriate reactive ionic etching or ionic machining) to eliminate the layer 24 of insulation located under the metal tracks 22 in the portion that has been etched.

This produces the integrated circuit represented in FIG. 2, which therefore includes a first substrate portion 30 that corresponds to the first region 2 of the substrate described above and a second substrate portion 32 that corresponds to the second region 4 referred to above.

Because of the total elimination of the substrate (and of the layer 24 of insulation) at the boundary 3 between the regions 2, 4, in particular by means of the etching previously referred to, the first portion 30 is separated from the second portion 32 by a gap 31, the two portions 30, 32 now being mechanically connected to each other only by the metal tracks 22.

The integrated circuit obtained is also shown in perspective in FIG. 3.

Thanks to the possibility of bending the integrated circuit (i.e. of rotating the second portion 32 relative to the first portion 30 as indicated by the arrow R in FIG. 3) offered by the hinge consisting of the metal tracks 22 thanks to their deformability perpendicularly to their surface, the second portion 32 can be inclined relative to the first portion 30 as described hereinafter, for example at an angle of up to 90°, which here enables the sensor 16 to be oriented so that it can measure efficiently the component of the magnetic field in the direction Z.

The first portion and the second portion can then be fastened together (i.e. the second portion can be immobilized relative to the first portion), either directly (for example by gluing), or via another portion as described hereinafter.

FIG. 4 represents the same component on which another integrated circuit 34 (for example an application-specific integrated circuit (ASIC)) has been mounted using the flip-chip technique.

Using this technique, the face of the integrated circuit 34 carrying the contacts is placed in contact with the front face of the component, which carries the magnetic field sensors 12, 14, 16 and the connection studs 18, with conductive balls 36 between them that make the electrical connection of each of the connection studs 18 to corresponding contacts (or studs) of the microcircuit 34 using the ball bonding technique.

The integrated circuit 34 further includes means 38 for connecting it to an external device and/or remote power feed and/or transmission antennas.

Thus the integrated circuit 34 can provide signal shaping, power supply and signal processing functions for the electrical signals transmitted to the magnetic sensors 12, 14, 16 and received therefrom in order to generate, for example in its connection means 38, processed signals representing (for example in digital form) the components of the magnetic field measured by the sensors 12, 14, 16.

As explained above, the sensors 12, 14 respectively measure the components of the magnetic field in the directions Y and X.

In order to obtain by means of the sensor 16 the component of the magnetic field in the direction Z (perpendicular to the main face of the substrate 10 as already mentioned), the second portion 32 is bent relative to the first portion 30 at the hinge formed by the metal tracks 22 whose flexibility (resulting, for example, from the fact that they are produced in a plastic metal, here copper, or alternatively gold) enables deformation without risk of breakage.

In the embodiment shown in FIG. 4, the bending corresponds to rotation about one of the axes forming the plane of the substrate (here the Y axis) as indicated by the arrow R in FIG. 4, which enables positioning of the second portion 32 above the plane formed by the substrate and that contains the first and second sensors 12, 14, near one edge of the integrated circuit 34 (here a flank of the integrated circuit 34), which can moreover provide a mechanical stop for the second portion 32. The second portion 32 can thus be fastened to the first portion 30 via the integrated circuit 34, for example by gluing the second portion 32 to the integrated circuit 34.

This produces a particularly compact magnetic field measuring device in which the third magnetic sensor 16 is placed in a plane inclined to (here even perpendicular to) that which contains the other two sensors 12, 14, which ensures efficient measurement of the three components of the magnetic field.

As already indicated above, it will be noted that the electrical connection between this third magnetic sensor 16 located in a plane perpendicular to that of the main substrate (first portion 30) is provided in particular by some of the deformed metal tracks 22, themselves electrically connected to the main portion of the connection studs 18 and therefore to the integrated circuit 34 via the conductive balls 36.

Flexible deformation of the metal tracks 22 therefore provides not only for ensuring relative mechanical retention of the two substrate portions to each other, but also ensures electrical continuity of the connection between these two portions, despite the strong inclination of one portion relative to the other.

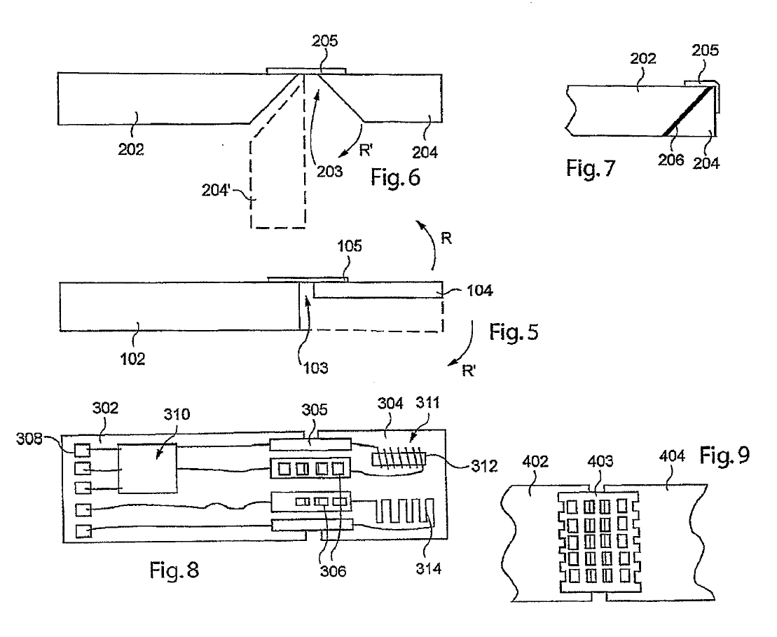

FIG. 5 is a diagram of a component conforming to a second embodiment of the invention.

In this second embodiment, the component includes a first substrate portion 102 (which can carry elements of electrical and/or electronic circuits, not shown) and a second portion 104 that is thinner compared to the thickness of the substrate 102 (which also carries circuits, not shown, that it is required to dispose in a plane inclined relative to that of the substrate). The first portion 102 and the second portion 104 are separated by a gap 103 and are mechanically connected by a plurality of metal tracks (or strips) 105 analogous to the metal tracks described above with reference to the first embodiment.

The FIG. 5 component is obtained from a plate-shaped silicon substrate, for example, as represented in dashed line in FIG. 5), in which etching has removed only a portion of the thickness in the second portion 104 and the whole of the thickness in the gap 103.

To do this, a first etching step is effected, for example, using a mask that covers only the first portion 102, to eliminate a portion of the thickness of the substrate, leaving only the thickness of the second portion 104, then a second etching step with a mask that covers all of the first and second portions 102, 104, except in the boundary area between these two portions, which enables the substrate to be eliminated throughout its thickness only in this boundary area of limited extent, and thus to obtain the gap 103.

Alternatively, mechanical pregrinding of the boundary area intended to receive the gap 103 (for example with a grinding tool or a string of grinding tools) so that, during a subsequent step of etching this area and the second portion 104, the boundary area is etched throughout the thickness of the substrate whereas the second portion 104 retains the required remanent thickness.

There can naturally be provided, prior to the etching step that had just been mentioned, a grinding step to thin the entire substrate. This possibility can also be envisaged for the other embodiments.

In this second embodiment, in particular in the case of bending in the rotation direction R′ indicated below, the thickness of the second portion 104 is of the order of (and preferably slightly less than) the width of the gap 103 (in particular, the distance between the first portion 102 and the second portion 104).

Thus the second portion 104 cannot be moved by bending about the hinge formed by the metal tracks 105, either in the rotation direction R identical to that referred to in connection with the first embodiment or in the opposite direction R′, whereby the second portion 104, once inclined, remains under the plane of the first portion 102 that carries metal tracks 105.

In the latter case, the thinness of the second portion 104 avoids the overall size problems that could prevent significant inclination of the second portion 104.

FIG. 6 represents another embodiment in which such problems are also avoided.

To this end, the gap 203 between a first portion 202 of the substrate and a second portion 204 of the substrate with a beveled etching profile, for example by means of a KOH type silicon etching medium, so that, when the second portion 204 is bent around the hinge formed by metal tracks 205 analogous to those already described, the beveled face at an angle close to 45° to the second portion 204 faces the beveled face of the first portion 202 at an angle close to 45°: thus an angle of bending of the second portion 204 can be obtained, running for example up to 90° (as represented in dashed line under the reference 204′ in FIG. 6) with no mutual mechanical impediment of the portions during rotation (in the direction R′) of the second portion 204 relative to the first portion 202. Rotation in the direction R (opposite to the direction R′) is also possible in this context.

FIG. 7 represents a variant in which the extent of the second portion 204 in the plane of the substrate before bending and gluing is limited to the thickness of the substrate, enabling production, after bending, and then deposition of a bead 206 of glue, of the particularly compact arrangement shown in FIG. 7. When the angles of the beveled surfaces are close to 45°, the glue joint 206 can also slightly compensate the bending angle to approximate or even achieve an angle of 90°.

FIG. 8 represents a plan view of another embodiment of the invention.

In this embodiment, a plate-shaped first portion 302 is separated from a plate-shaped second portion 304 and connected to the latter by metal elements 305 adapted to be deformed. Note that the metal elements 305 are produced in the form of strips and that some of these include one or more holes 306, for example to reinforce (thanks to the braiding which forms angular points generating mechanical stresses in the metal strips) or more generally to adapt the mechanical resistance to bending of each of the strips to the requirements of the application.

The first portion 302 includes connecting lands 308 and a circuit (for example a first integrated circuit) diagrammatically represented by the reference number 310. The second portion 304 carries a second integrated circuit 311, including, for example, in the FIG. 8 illustration, an inductive component 312 and a magnetoresistive serpentine 314.

As can be seen in FIG. 8, some connection studs 308 are electrically connected to the first integrated circuit 310, while the circuits 312 and 314 of the second integrated circuit 311 are connected to other connection studs 308, in particular via deformable metal tracks 305. There could equally be provision for at least some of the circuits 312 and 314 of the second integrated circuit 311 to be connected to the first integrated circuit 310 (and not to the connection studs 308) via the metal tracks 305.

The component is obtained by bending the device represented in FIG. 8 about the hinge formed by the deformable metal tracks 305, that is to say by moving (here in rotation) the second portion 304 relative to the first portion 302.

The circuits 312, 314 in the second portion 304 can therefore be situated there in a plane inclined (for example at an angle of 90°) to the first portion 302, the metal tracks 305 deformed during this movement continuing to provide the electrical connections referred to above between the elements 312 and 314 of the second portion 304 and the studs and circuits 308, 310 of the first portion 302.

FIG. 9 represents a variant in which the deformable connecting means do not take the form of a plurality of tracks or strips (partial trellis), but instead the form of a trellis that covers a significant proportion of (or even all of) the hinge, which in some cases ensures a better mechanical connection between the first portion 402 and the second portion 404 joined by that trellis.

The embodiments that have just been described merely constitute possible examples of the use of the invention.

1. An integrated circuit comprising a plate-shaped first portion, and at least one plate-shaped second portion separate from the first portion and attached to the first portion, wherein the second portion is connected to the first portion by deformable mechanical connecting means defining a non-zero angle with respect to the first portion.

2. The integrated circuit according to claim 1, wherein the connecting means at least partly comprises a metal.

3. The integrated circuit according to claim 1, wherein the connecting means comprises at least one metal wire fastened to the first portion at a first end and to the second portion at a second end.

4. The integrated circuit according to claim 1, wherein the connecting means comprises at least one metal trellis connected to the first portion and to the second portion.

5. The integrated circuit according to claim 1, wherein the connecting means comprises copper or gold.

6. The integrated circuit according to claim 1, wherein the first portion comprises a silicon plate.

7. The integrated circuit according to claim 1, wherein the non-zero angle is greater than 60°.

8. The integrated circuit according to claim 1, wherein the non-zero angle is approximately 90°.

9. The integrated circuit according to claim 1, wherein the second portion includes an electrical element and wherein the connecting means contribute to an electrical connection between an electrical circuit in the first portion and the electrical element in the second portion.

10. The integrated circuit according to claim 1, wherein the first portion includes at least one sensor adapted to measure a component of a magnetic field in a direction parallel to a main surface of the first portion and wherein the second portion includes a sensor adapted to measure a component of the magnetic field in a direction parallel to a main surface of the second portion.

11. The integrated circuit according to claim 10, wherein the sensors comprise micro-fluxgate sensors.

12. The integrated circuit according to claim 10, wherein said sensors are magnetoresistive sensors.

13. The integrated circuit according to claim 10, wherein said sensors are magneto-impedance sensors.

14. The integrated circuit according to claim 10, wherein said sensors are Hall-effect sensors.

15. The integrated circuit according to 1, wherein the first portion includes a plurality of connection studs and wherein a second integrated circuit having second connection studs is mounted in contact with the first portion with electrical connections between at least one of the second connection studs and one of said the first connection studs.

16. The integrated circuit according to claim 15, wherein the second portion is proximate to a flank of the second integrated circuit.

17. A method of producing an integrated circuit from a plate-shaped structure, the method comprising:
depositing deformable connecting means in contact with a first portion of the structure and a second portion of the structure;
etching the structure to separate the first portion and the second portion;
relatively moving the first and second portions to deform the connecting means; and
fastening together the first portion and the second portion.

18. The method according to claim 17, wherein relatively moving comprises a rotation of the second portion relative to a hinge formed by the connecting means.

19. The method according to claim 17, wherein the connecting means comprises at least one metal wire fastened to the first portion at one end and to the second portion at the other end.

20. The method according to claim 17, wherein the connecting means comprises at least one metal trellis connected to the first portion and to the second portion.

21. The method according to claim 17, wherein the connecting means comprise copper or gold.

22. The method according to claim 17, wherein the structure comprises a silicon substrate.

23. The method according to claim 17, further comprising thinning the structure before etching.

24. The method according to claim 17, further comprising ,before etching, partially grinding an area subjected to the etching.

25. The method according to claim 17, wherein depositing deformable connecting means comprises forming an electrically conductive material and wherein the method further comprises depositing a conductor between at least one circuit in the first portion or the second portion of the structure and the connecting means.

26. The method according to claim 25, further comprising depositing a conductor between the connecting means and a circuit element on the first portion.

27. The method according to claim 17, wherein etching the structure comprises anisotropic etching.

28. The method according to claim 17, further comprising assembling a face of the second portion that has been subjected to etching with an edge of the first portion.

29. The method according to claim 17, wherein etching the structure comprises forming an inclined profile on a face of each of the first and second portions.

30. The method according to claim 29, further comprising, after relatively moving the first and second portions, assembling the inclined profile face of the second portion against the inclined profile face of the second portion.

31. An integrated circuit comprising a plate-shaped first portion, and at least one plate-shaped second portion separate from the first portion and attached to the first portion by a deformable mechanical connection defining a non-zero angle with respect to the first portion.
